(19) United States
(12) Patent Application Publication
(10) Pub. No.: US 2014/0124018 A1
(43) Pub. Date: May 8, 2014

(54) Photovoltaic Panel Racking System

(71) Applicant: Georgia Tech Research Corporation, Atlanta, GA (US)

(72) Inventors: Joseph Goodman, Atlanta, GA (US); Jamie Porges, Atlanta, GA (US); Kayeon Lee, Seoul (KR); Andrés Cavieres, Atlanta, GA (US); Peter Fitzpatrick, Atlanta, GA (US); Tristan Al-Haddad, Clarkston, GA (US)

(73) Assignee: Georgia Tech Research Corporation, Atlanta, GA (US)

(21) Appl. No.: 14/073,780

(22) Filed: Nov. 6, 2013

Related U.S. Application Data
(60) Provisional application No. 61/823,471, filed on May 15, 2013.
(60) Provisional application No. 61/723,124, filed on Nov. 6, 2012.

(51) Int. Cl. H01L 31/042

(52) U.S. Cl. CPC H01L 31/0422
USPC 136/251; 29/428; 211/41.1

(57) ABSTRACT

A photovoltaic panel racking system is provided having multiple beams aligned in parallel relation where multiple photovoltaic panels are mounted on top of the beams. The beams have a wave structure with multiple sets of slopes providing multiple mounting points. The photovoltaic panel racking system provides a low cost, easy to install and manufacture photovoltaic panel installation solution for roof tops and other surfaces.

### CROSS-REFERENCE TO RELATED APPLICATIONS

This application is a non-provisional application which claims the benefit to Provisional Application No. 61/823,471 filed on May 15, 2013 and Provisional Application No. 61/723,124 filed on Nov. 6, 2012.

### BACKGROUND

1. Field of the Invention

The present invention relates generally to photovoltaic panel installation systems. More particularly, the present invention relates to a photovoltaic panel racking system that provides easy installation and cost savings.

2. Description of Related Art

Photovoltaic panels are an environmentally friendly solution to generating electricity. However, they are an expensive solution not only because of the cost of photovoltaic panels themselves, but also because of the cost of installing the photovoltaic panels. Typically, installation of photovoltaic panels requires highly trained installers and many hours of labor to properly align the panels and install them securely and accurately.

The installation of photovoltaic panels on a roof requires flexibility in configuration and arrangement because the roof size and shape vary from building to building. Thus, custom racking systems typically need to be designed for individual installation surfaces.

Therefore, what is needed is a photovoltaic panel racking system that requires less time and skill to install, reducing the overall installation costs.

### SUMMARY

The subject matter of this application may involve, in some cases, interrelated products, alternative solutions to a particular problem, and/or a plurality of different uses of a single system or article.

In one aspect, a mounting rack for installing a photovoltaic panel on a surface is provided. The mounting rack may be constructed of a length of a beam where the beam may be bent to form a first segment and a second segment. The first segment, having a first length, may extend from the surface at a first angle upward and away from the surface. The second segment, having a second length, may extend further from an end of the first segment towards the surface at a second angle ending when the second segment meets the surface. Each of the first and second segments may provide a first top surface and a second top surface respectively. A plurality of second mounting points may be formed along the second top surface providing a platform where one or more photovoltaic panels may be removably attached.

In another aspect, a photovoltaic panel racking system for a surface is presented. The photovoltaic panel racking system may comprise a plurality of photovoltaic panels which may have a rectangular body. The system may further comprise a plurality of beams. The plurality of beams may form a plurality of first slopes rising upwardly and away from the surface at a first angle. A plurality of second slopes may be formed downwards and towards the surface at an interval, contiguously connecting each of the plurality of first slopes. The plurality of first slopes and the plurality of second slopes may have a first length and a second length respectively. Moreover, each of the plurality of beams may be formed in a straight structure wherein each of the first slopes and each of the second slopes rest within the plane thereof.

In yet another aspect, a method of installing a photovoltaic panel racking system on a surface is provided. The method may begin with arranging a plurality of beams in parallel at a distance accommodating a size of a photovoltaic panel. A plurality of photovoltaic panels may be mounted across the plurality of beams, creating rows of photovoltaic panels. The mounted photovoltaic panels may be configured to have an electrical bonding path. A plurality of wind deflectors may be mounted in between each of the rows of photovoltaic panels. Finally, a plurality of ballast bases may be mounted at least to one of the plurality of beams, anchoring the photovoltaic racking system to the surface.

### BRIEF DESCRIPTION OF THE DRAWINGS

FIG. 1 provides a side view of an embodiment of the mounting rack for photovoltaic panel installation on a surface.

FIG. 2 provides isometric views of another embodiment of the mounting rack.

FIG. 3 provides one of the plurality of beams comprising the photovoltaic panel racking system.

FIG. 4 provides an embodiment of the photovoltaic panel racking system comprising two of the plurality of beams.

FIG. 5 provides an embodiment of the photovoltaic panel racking system.

FIG. 6 provides one end of one of the plurality of beams comprising the photovoltaic panel racking system.

FIG. 7 provides the other end of one of the plurality of beams.

FIG. 8 provides a detailed view of the wind deflectors and the ballast base.

FIG. 9 provides an embodiment of the photovoltaic panel racking system with the ballast base.

FIG. 10 provides another embodiment of the photovoltaic panel racking system with the ballast base.

FIG. 11 provides an embodiment of the ballast base integrated with each of the plurality of wind deflectors.

FIG. 12 provides an embodiment of the ballast base being filled by a hose.

FIG. 13 provides an embodiment of the mounting means formed at each end of the beam.

FIG. 14 provides an embodiment of one of the plurality of beams in flat structure.

### DETAILED DESCRIPTION

The detailed description set forth below in connection with the appended drawings is intended as a description of presently preferred embodiments of the invention and does not represent the only forms in which the present invention may be constructed and/or utilized. The description sets forth the functions and the sequence of steps for constructing and operating the invention in connection with the illustrated embodiments.

Photovoltaic panels are commonly installed on top of a roof. In order to install the photovoltaic panels, a racking system is commonly placed with precise measurement for structural support and durability. Current photovoltaic panel racking systems have several shortcomings including complications in installation, and being difficult to assemble and maintain.

The photovoltaic racking system described herein simplifies installation process of photovoltaic panels by providing a reference guide and indexing mechanisms for easy and quick alignment and squaring of photovoltaic panels on top of a flat roof. A plurality of mounting beams are bent and fabricated to allow the photovoltaic panels to be installed without a rigorous measurement process, thereby simplifying the installation process. Moreover, mounting points are formed on top of the plurality of mounting beams to enable accurate installation of the photovoltaic panels. The photovoltaic racking system described herein is also designed to be modular. The modular structure allows the photovoltaic racking system to be easily shipped, stacked, manufactured and repaired. Additionally, the claimed invention achieves these results without the need for a complex, cumbersome and costly training of professional installers.

The photovoltaic racking system and its components may be constructed of any material that may withstand and support the weight of the photovoltaic panels in all weather conditions without substantial damage or deformation. Materials of which may include, but not limited to, metals such as steel, stainless steel, aluminum, titanium, and the like, ceramic composites, composite reinforced metals, plastic and the like. In one embodiment, the photovoltaic racking system and its components may be constructed of a conductive metal to provide an electrical bonding path.

Generally, the disclosed invention concerns a mounting rack for photovoltaic panel installation on a surface. The disclosed invention may be a modular unit allowing an extension of a photovoltaic panel array both lengthwise and width wise. In addition, the disclosed invention concerns integration of a ballast base and a wind deflector to the mounting rack which may be aerodynamically configured to increase stability of the mounting rack for photovoltaic panel installation.

A mounting rack for photovoltaic panel installation on a surface may be constructed of a length of a beam. In one embodiment, the beam may be bent to form a first segment and a second segment with a first length and a second length respectively. The first segment may extend from the surface at a first angle upwardly and away from the surface. The second segment may extend further from an end of the first segment at a second angle downwardly and towards the surface making contact with the surface. The first segment and the second segment may respectively form a first top surface and a second top surface where a plurality of second mounting points may be formed along the second top surface. In another embodiment, the mounting rack may extend further along the surface at each ends of the beam making further contact with the surface.

The first length, the second length, the first angle, and the second angle may be of any variations that may receive, withstand and support the weight of the photovoltaic panels in all weather conditions without substantial damage or deformation.

The plurality of second mounting points may be sized to removably receive one edge of a photovoltaic panel. In one embodiment, the photovoltaic panel may have a rectangular body. In another embodiment, the photovoltaic panel may be of any size and configuration that may removably mate with the plurality of second mounting points.

In one embodiment, each of the plurality of second mounting points may be a clip-in mechanism where each of the plurality of second mounting points may form a slot underneath the second top surface within the second segment. The slot may have an opening to removably receive one edge of the photovoltaic panel. In another embodiment, the plurality of second mounting points may be configured to receive two of the photovoltaic panels, where each of the two may be placed adjacent to each other sharing the plurality of second mounting points formed on the second top surface.

The first segment may also be designed to receive a structure. The mounting rack may further comprise a plurality of first mounting points formed along the first top surface.

The mounting rack disclosed herein may be a modular unit. The mounting rack may be mechanically bonded to extend further duplicating the same structure and function.

A multiple of mounting rack may be formed contiguously to form a photovoltaic panel racking system allowing arrays of the photovoltaic panel to be mounted. The photovoltaic panel racking system for a surface may comprise a plurality of photovoltaic panels, a plurality of beams, and a plurality of mounting points

In one embodiment, the plurality of photovoltaic panels may each have a rectangular body. In another embodiment, the plurality of beams may have a plurality of first slopes having a first angle upwardly and away from the surface. Each of the plurality of first slopes may be contiguously connected at an interval by a plurality of second slopes connecting each of the plurality of first slopes at a second angle. The plurality of first slopes may extend at a first length and the plurality of second slopes may extend at a second length.

In one embodiment, the plurality of beams may form a straight structure within the plane thereof. In another embodiment, the first length, the second length, the first angle, and the second angle may be of any variations that may receive, withstand and support the weight of the photovoltaic panels in all weather conditions without substantial damage or deformation. In yet another embodiment, each of the plurality of beams may be placed at a distance away from one another to form a parallel arrangement where the distance may be configured to mount two opposite edge of each of the plurality of photovoltaic panels.

The plurality of mounting points may be formed along a top surface of each of the plurality of beams and may be configured to removably mount each of the plurality of photovoltaic panels at each of the plurality of mounting points.

In one embodiment, each of the plurality of mounting points may be a clip-in mechanism where each of the plurality of mounting points may form a slot underneath the top surface of each of the plurality of beams within each of the plurality of beams. The slot may have an opening to removably receive one edge of the photovoltaic panel. In another embodiment, the plurality of mounting points may be configured to receive two of the photovoltaic panels, where each of the two may be placed adjacent to each other sharing the plurality of mounting points formed along the top surface of one of the plurality of beams.

The photovoltaic panel racking system may further comprise another structure removably mounted to the plurality of mounting points.

In one embodiment, the photovoltaic panel racking system may further comprise a plurality of indexing means.

Each of the plurality of indexing means may be configured to removably mate with each of the plurality of mounting points formed along the top surface of each of the plurality of beams, connecting the plurality of beams, and indexing and aligning the plurality of beams. Indexing provides a precise alignment and placing of the plurality of beams. The plurality of indexing means may removably mate with each of the plurality of mounting points prior to a mounting of the plurality of photovoltaic panels, thereby providing indexing.

In another embodiment, the photovoltaic panel racking system may further comprise a plurality of wind deflectors where each of the plurality of wind deflectors may be substantially flat in structure and may be configured to removably mate with each of the plurality of mounting points formed along each of the plurality of first slopes, thereby connecting the plurality of beams. Further, each of the plurality of wind deflectors may index and align the plurality of beams. Each of the plurality of wind deflectors may mate with each of the plurality of mounting points at the first angle as each of the plurality of first slopes.

In a further embodiment, the photovoltaic panel racking system may further comprise a ballast base. The ballast base may be sized to be removably attached between each of the plurality of beams. The ballast base may index and align the plurality of beams. The ballast base may be configured to have a weight to anchor the photovoltaic panel racking system, thereby stabilizing the photovoltaic panel racking system.

In one embodiment, the ballast base may be of any size and shape that may be sufficient to anchor the photovoltaic panel racking system down to the surface and be removably mountable between each of the plurality of beams.

In another embodiment, the ballast base may form a cavity therein, fillable with a ballast material. The ballast material may be of any material substantially heavy in weight to act as an anchor providing stability to the photovoltaic panel racking system. The ballast material may include, but not limited to, water, sand, concrete, and the like.

In yet another embodiment, the ballast base may be integrated with each of the plurality of wind deflectors. The ballast base may be constructed of a solid material and substantially flat and heavy. The ballast base may be configured to removably mate with each of the plurality of mounting points formed along each of the plurality of first slopes.

The photovoltaic panel racking system may be modular, therefore allowing an array of photovoltaic panels to be further mounted if needed. The photovoltaic panel may be flexible in configuration allowing expansion lengthwise. In one embodiment, the photovoltaic panel racking system may further comprise an extending means which may be formed at each end of the plurality of beams. The extending means may be configured to removably attach one or more of the plurality of beams, extending the photovoltaic panel racking system lengthwise and within the plane thereof.

The photovoltaic panel racking system may further comprise a mounting means which may be formed at each end of each of the plurality of beams. The mounting means may be configured to securely connect each of the plurality of beams to the surface.

The photovoltaic panel racking system may further comprise a plurality of foot pads which may be formed at one or more contact points where each of the plurality of beams touches the surface. Each of the plurality of foot pads may be made of a shock absorbing material or the like, providing dampening to any vibration the photovoltaic panel racking system may encounter in some weather conditions.

In one embodiment, each of the plurality of beams may be foldable. The first angle and the second angle of the plurality of beams may be adjustable within the plane thereof, allowing the plurality of beams to be a flat structure.

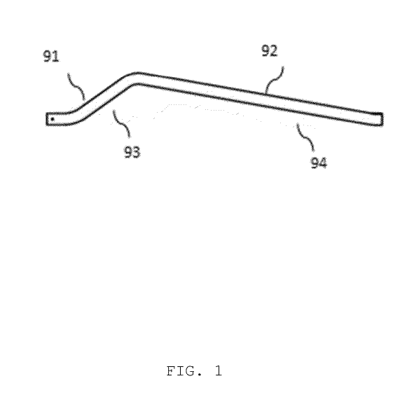

Turning now to FIG. 1, a side view of an embodiment of the mounting rack for photovoltaic panel installation on the surface is shown. The mounting rack is formed of a length of a beam bent to form the first segment 93 having the first top surface 91 extending upwardly and away from the surface. The second segment 94 is formed from the end of the first segment 91 downwards and contacting the surface providing the second top surface 92. Each end of the mounting rack of FIG. 1 is contacting the surface at a level.

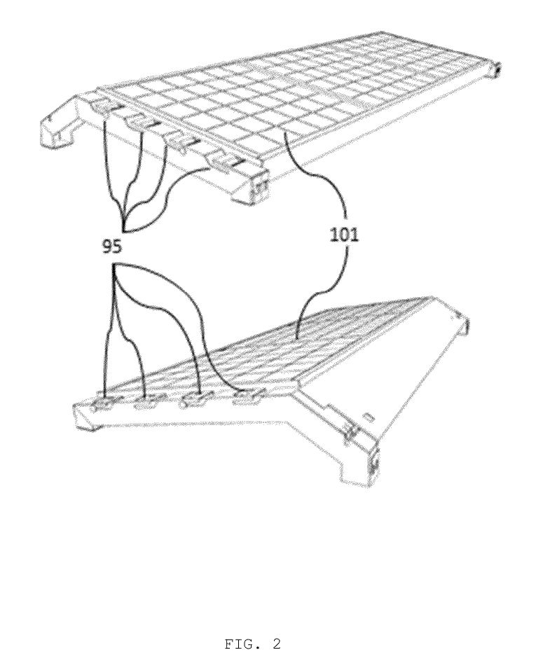

FIG. 2 shows isometric views of another embodiment of the mounting rack with the plurality of slots 95 formed underneath the second top surface. The plurality of slots 95 is an embodiment of the plurality of second mounting points. In this embodiment, an array of the plurality of photovoltaic panels 101 is shown mounted on the plurality of slots 95. Each of the plurality of slots 95 has an opening formed to removably receive one edge of the photovoltaic panel.

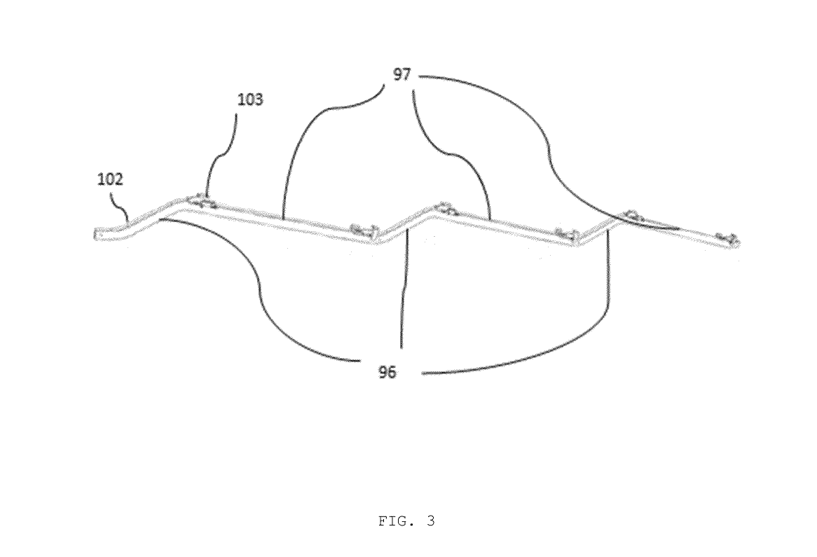

FIG. 3 illustrates one of the plurality of beams comprising the photovoltaic panel racking system. The one of the plurality of beams 102 forms the plurality of first slopes 96 extending upwardly and away from the surface. The plurality of second slopes 97 contiguously connects each of the plurality of first slopes 96 at an interval where each of the plurality of second slopes 97 extend from an end of the each of the plurality of first slopes 96 downwards and towards the surface. The one of the plurality of beams 102 forms a straight structure within the plane thereof. The plurality of mounting points 103 are formed along the top surface of the one of the plurality of beams 102.

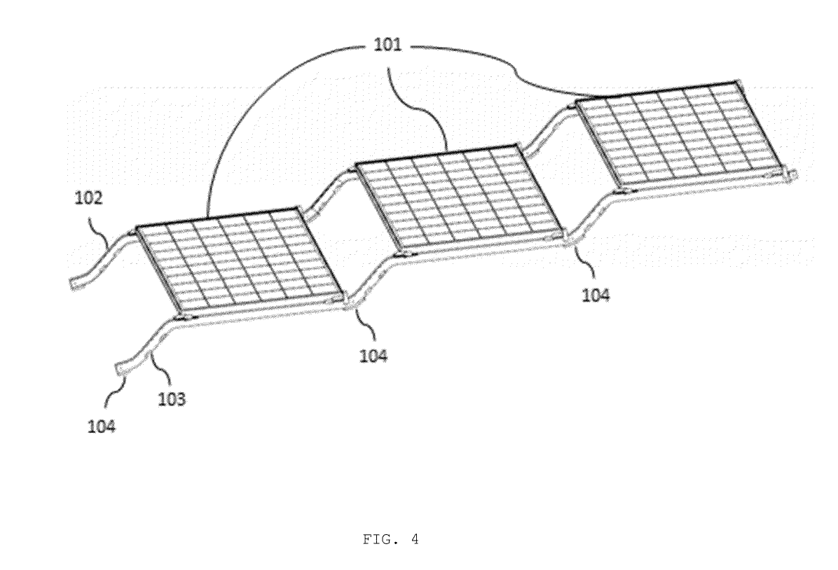

FIG. 4 shows an embodiment of the photovoltaic panel racking system comprising two of the plurality of beams 102 placed in parallel to each other spaced by a width of the plurality of photovoltaic panels 101. The plurality of mounting points 103 are shown along each of the plurality of second slopes. The plurality of foot pads 104 are placed at each contact points where the plurality of beams 102 touches the surface. The plurality of foot pads 104 dampens the vibrational movement which may occur during the lifetime of the photovoltaic panel racking system.

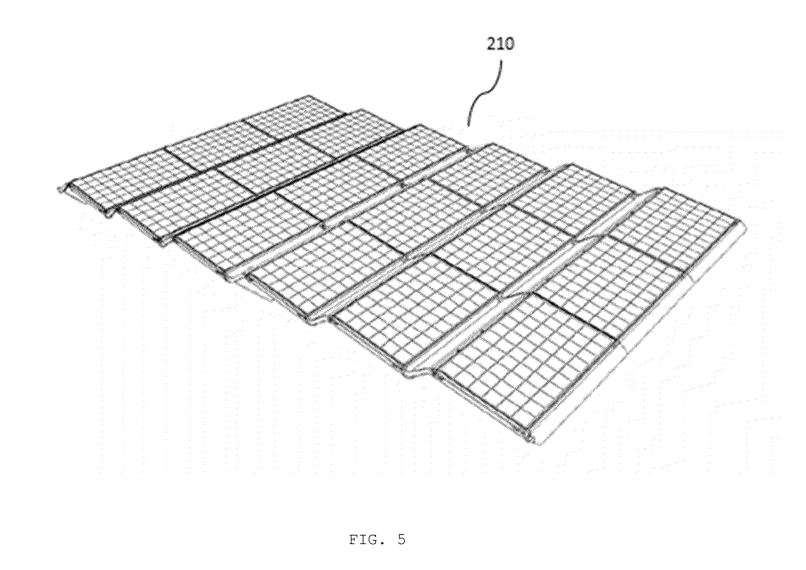

Now turning to FIG. 5, another embodiment of the photovoltaic panel racking system 210 is shown. This embodiment shows four of the plurality of beams mounting three of the plurality of photovoltaic panels transversely and adjacent to one another at each of the second slopes. The middle two beams receives two of the plurality of photovoltaic panels where the two solar panels shares the plurality of mounting points formed along one of the two beams.

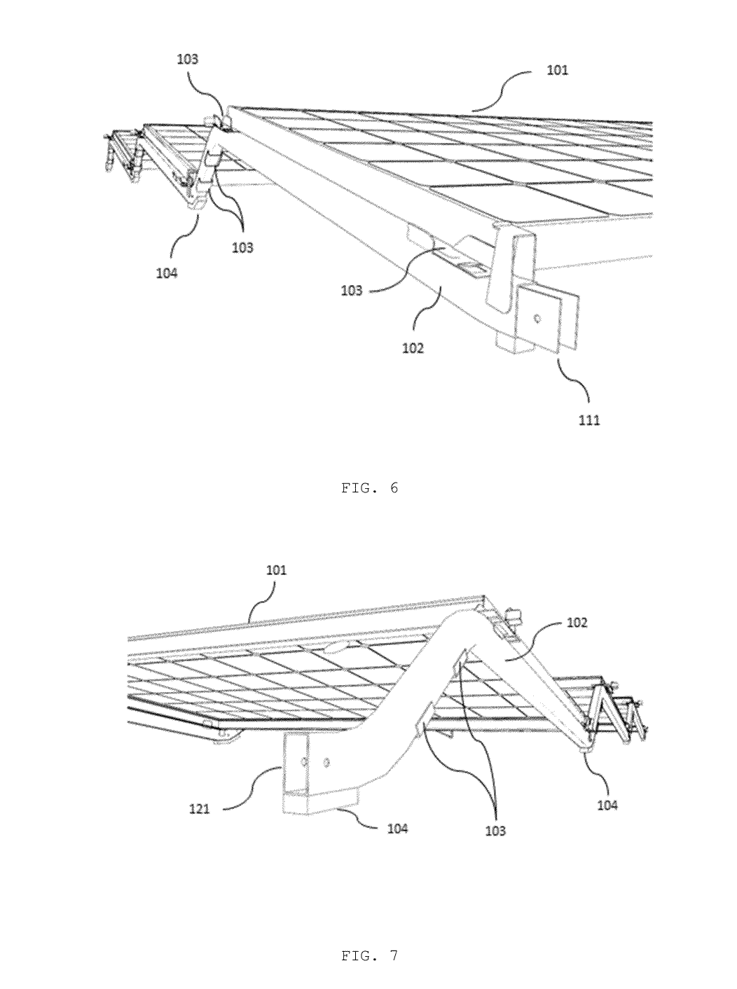

FIG. 6 shows one end of one of the plurality of beams 102 comprising the photovoltaic panel racking system. FIG. 7 shows the other end of one of the plurality of beams 102 comprising the photovoltaic panel racking system. The extending means 111, 121 are formed at each end of one of the plurality of beams 102. The extending means 111, 121 enable the beam 102 to extend further lengthwise. The extending means 111 and 121 are removably mountable. The plurality of mounting points 103 are shown formed along the top surface of the beam. Further, the foot pads 104 are shown removably mounted at each contact points where the beam 102 touches the surface.

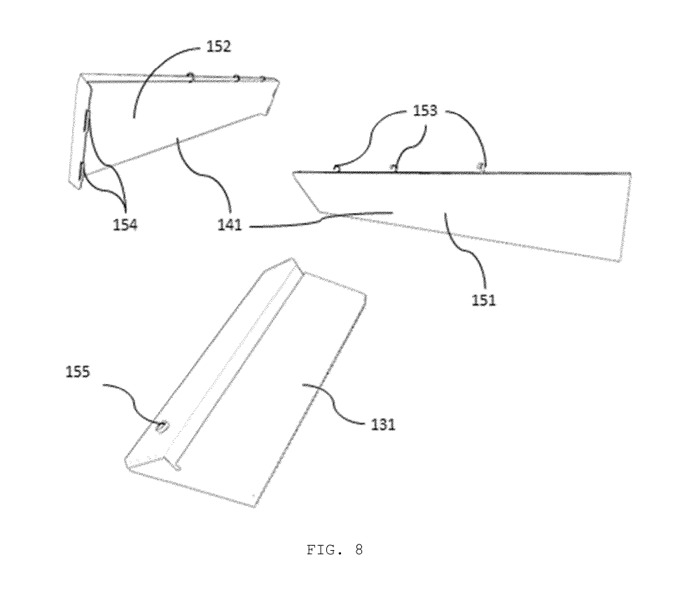

FIG. 8 shows one of the wind deflectors 141 and the ballast base 131. In this embodiment, the wind deflector 141 forms a series of hooks 153 and a series of slots 154 removably mountable to one of the plurality of mounting points. A top surface of the wind deflector 141 is shown to have a flat surface 151 and 152. An aperture 155 is formed to the ballast base 131 providing an access to the cavity of the ballast base 131 which is fillable with the ballast material.

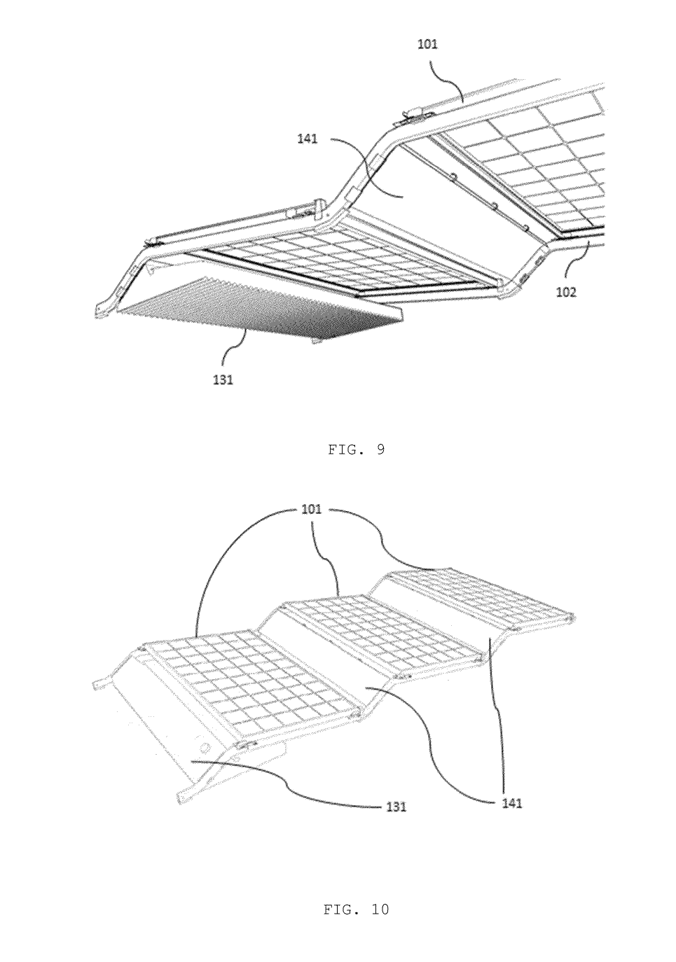

FIGS. 9 and 10 shows the photovoltaic panel racking system with the ballast base 131 and the plurality of wind deflectors 141 removably mounted by the plurality of mounting points formed along the top surface of the beams 102. The plurality of photovoltaic panels 101 are also shown mounted in a similar manner.

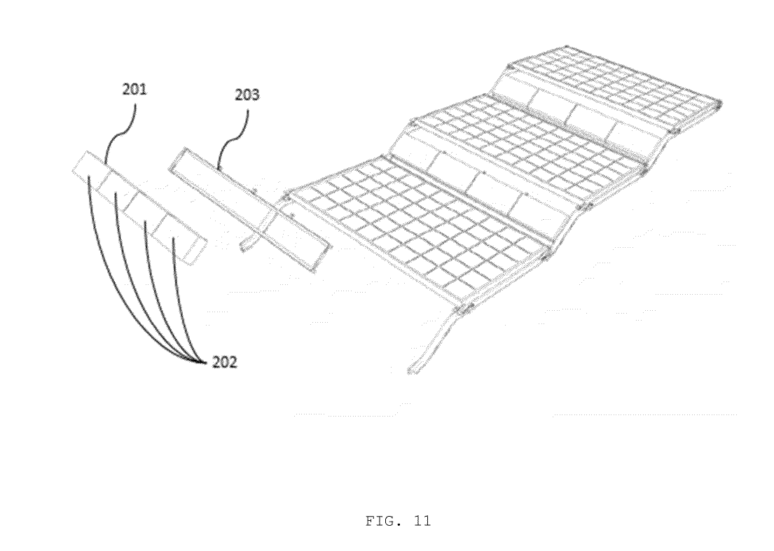

FIG. 11 shows an embodiment of the ballast base integrated with each of the plurality of wind deflectors. The ballast base 202 is constructed of a solid material and substantially flat and heavy. In this embodiment, the ballast base is constructed of a plurality of blocks 202 and configured to rest on top of a frame 203. The plurality of blocks 202 forms a flat surface once removably mounted on the plurality of first slopes.

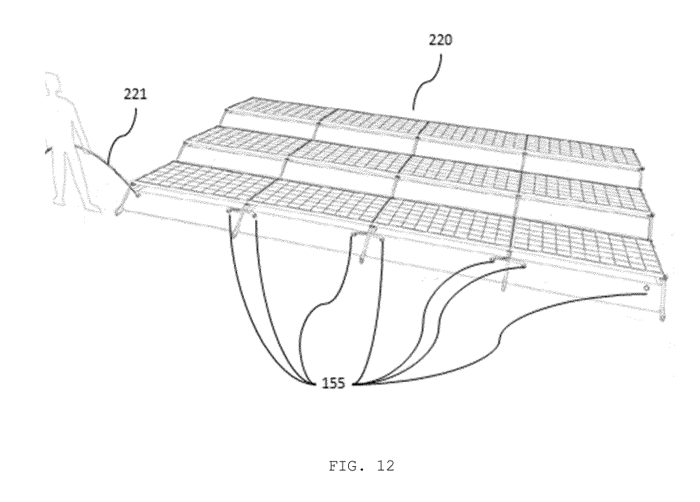

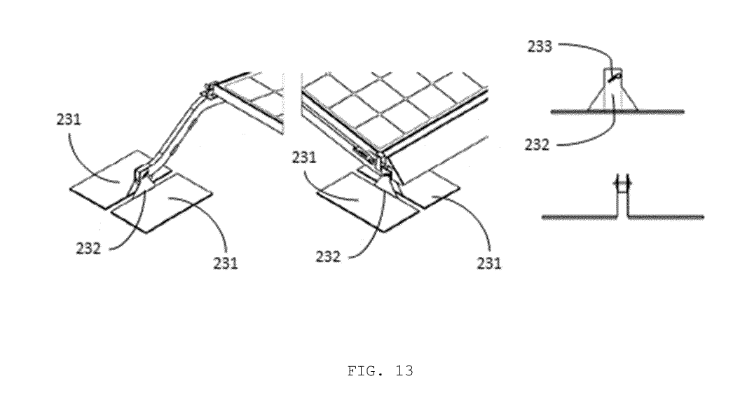

FIG. 12 illustrates an embodiment of the ballast base being filled by a hose 221. The photovoltaic panel racking system 220 is anchored by a plurality of ballast bases. Each of the plurality of ballast bases has a set of apertures 155 formed therein. The hose 221 connects each of the apertures 155 in a series allowing a liquid-base ballast material to fill the cavity of each of the plurality of ballast bases.

FIG. 13 shows an embodiment of the mounting means formed at each end of the beam. The mounting means comprises a set of mounting plates 231 and a mounting foot 232. The mounting foot 232 is placed and restrained by the set of mounting plate 231 securely connecting the beam to the surface. The mounting foot 232 is secured to each end of the beam by a secure lock 233 connected through and across the beam.

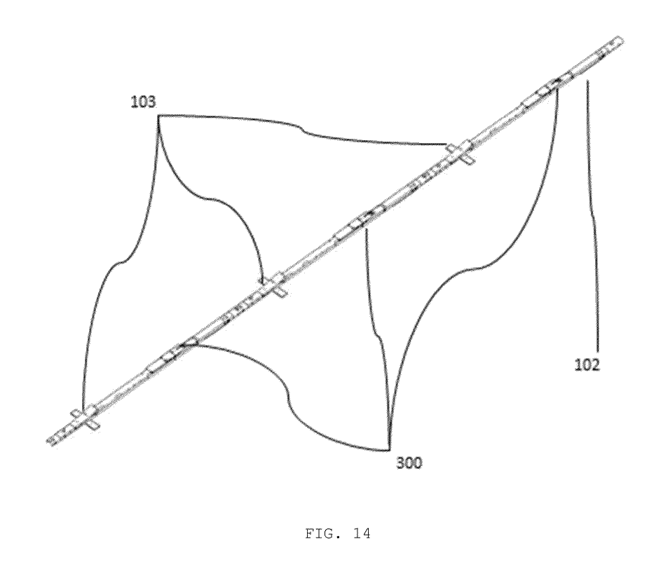

FIG. 14 shows an embodiment of one of the plurality of beams in flat structure. The plurality of beams 102 is foldable allowing the first angle and the second angle to be zeros with respect to the surface. The plurality of mounting points 103 is shown. A plurality of bending points 300 is folded down to create a flat beam without any slopes formed at an angle.

While several variations of the present invention have been illustrated by way of example in preferred or particular embodiments, it is apparent that further embodiments could be developed within the spirit and scope of the present invention, or the inventive concept thereof. However, it is to be expressly understood that such modifications and adaptations are within the spirit and scope of the present invention, and are inclusive, but not limited to the following appended claims as set forth.

What is claimed is:

1. A mounting rack for photovoltaic panel installation on a surface, wherein the mounting rack is constructed of a length of a beam bent to form a first segment and a second segment, having a first length and a second length respectively, the first segment extending from the surface at a first angle upwardly and away from the surface, the first segment providing a first top surface, the second segment extending at an end of the first segment downwardly at a second angle, making contact with the surface, the second segment providing a second top surface, and a plurality of second mounting points formed along the second top surface.

2. The mounting rack of claim 1 further comprising a photovoltaic panel having a rectangular body, wherein each of the plurality of second mounting points is sized to removably receive one edge of the photovoltaic panel.

3. The mounting rack of claim 2 further comprising a plurality of first mounting points formed along the first top surface.

4. The mounting rack of claim 2 wherein each of the plurality of second mounting points is configured to receive at least two of the photovoltaic panel, each of the two photovoltaic panels being placed adjacent to each other sharing each of the plurality of second mounting points.

5. A photovoltaic panel racking system for a surface, comprising:
a plurality of photovoltaic panels having a rectangular body;
a plurality of beams having a plurality of first slopes at a first angle upwardly and away from the surface having a first length, each of the plurality of first slopes being contiguously connected at an interval by a plurality of second slopes at a second angle downwardly and towards the surface having a second length, wherein each of the plurality of beams forms a straight structure within the plane thereof; and
a plurality of mounting points formed along a top surface of each of the plurality of beams, configured to removably mount each of the plurality of photovoltaic panels at each of the plurality of mounting points.

6. The photovoltaic panel racking system of claim 5 wherein each of the plurality of beams is placed at a distance away from one another in a parallel relation lengthwise, the distance being configured to mount two opposite edge of each of the plurality of photovoltaic panels.

7. The photovoltaic panel racking system of claim 5 wherein each of the plurality of mounting points is a plurality of slots, each of the plurality of slots being formed underneath the top surface of each of the plurality of beams within the each of the plurality of beams, each of the plurality of slots having an opening configured to removably receive one edge of the photovoltaic panel.

8. The photovoltaic panel racking system of claim 5 wherein each of the plurality of mounting points is configured to receive at least two of the plurality of photovoltaic panels, each of the two of the plurality of photovoltaic panels being placed adjacent to each other sharing the plurality of mounting points formed along the top surface of one of the plurality of beams.

9. The photovoltaic panel racking system of claim 5 further comprising a plurality of wind deflectors, each of the plurality of wind deflectors being substantially flat and configured to removably mate with each of the plurality of mounting points formed along each of the plurality of first slopes, connecting the plurality of beams, each of the plurality of wind deflectors mating at the first angle with respect to the surface, and each of the plurality of wind deflectors indexing and aligning the plurality of beams.

10. The photovoltaic panel racking system of claim 5 further comprising a mounting means formed at each end of each of the plurality of beams, wherein the mounting means is configured to securely connect each of the plurality of beams to the surface.

11. The photovoltaic panel racking system of claim 5 further comprising a plurality of foot pads formed at one or more contact points where each of the plurality of beams touches the surface.

12. The photovoltaic panel racking system of claim 5 further comprising a ballast base, wherein the ballast base is sized to be removably attached between each of the plurality of beams, the ballast base having a weight configured to anchor the photovoltaic panel racking system, and the ballast base indexing and aligning the plurality of beams.

13. The photovoltaic panel racking system of claim 12 wherein the ballast base has a cavity fillable with a ballast material.

14. The photovoltaic panel racking system of claim 13 wherein the ballast material is liquid.

15. The photovoltaic panel racking system of claim 5 wherein each of the plurality of beams is built with conducting material, providing an electrical bonding path along the photovoltaic panel racking system to the surface.

16. The photovoltaic panel racking system of claim 5 further comprising an extending means formed at each end of the plurality of beams, wherein the extending means is configured to removably attach one or more of the plurality of beams, extending the photovoltaic panel racking system lengthwise.

17. The photovoltaic panel racking system of claim 5 further comprising a plurality of indexing means, each of the plurality of indexing means configured to removably mate with each of the plurality of mounting points formed along each of the plurality of first slopes, connecting the plurality of beams, and indexing the plurality of beams.

18. The photovoltaic panel racking system of claim 5 wherein each of the plurality of beams is foldable, the first angle and the second angle being adjustable within the plane thereof, each of the plurality of beams being foldable to form a flat structure.

19. A method of installing a photovoltaic panel racking system on a surface, comprising the steps of:
placing each of a plurality of beams in parallel at an interval on top of the surface, wherein the distance is determined by each of a plurality of photovoltaic panels;
indexing the plurality of beams to receive each of the plurality of photovoltaic panels;
mounting a plurality of wind deflectors across each of the plurality of beams adjacent to each other, creating rows of wind deflectors transversely, the plurality of wind deflectors aligning and indexing the plurality of beams to receive each of the plurality of photovoltaic panels;
mounting each of the plurality of photovoltaic panels across each of the plurality of beams adjacent to each other;
configuring the photovoltaic racking system to have an electrical bonding path; and
mounting a plurality of ballast bases to at least one of the plurality of beams, anchoring the photovoltaic racking system to the surface, the plurality of ballast base aligning and indexing the plurality of beams to receive each of the plurality of photovoltaic panels.

20. The method of claim 19 further comprising the step of adjusting a weight of each of the plurality of ballast bases by filling a cavity of each of the plurality of ballast bases with ballast material.

21. The method of claim 20 wherein the step of adjusting the weight of each of the plurality of ballast bases comprises filling the cavity of each of the plurality of ballast bases with liquid.

22. The method of claim 19 further comprising the step of adjusting an angle of each of the plurality of photovoltaic panels.

23. The method of claim 19 further comprising the step of adjusting an angle of each of the plurality of wind deflectors.
